(19) United States
(12) Patent Application Publication
(10) Pub. No.: US 2017/0074909 A1
(43) Pub. Date: Mar. 16, 2017

(54) COMPUTER CONTROLLED AUTOMATED SAFE TO MATE METHOD AND APPARATUS

(71) Applicant: U.S.A. as represented by the Administrator of the National Aeronautics and Space Administration, Washington, DC (US)

(72) Inventors: PHUC H. NGUYEN, Severn, MD (US); MICHELLE B. SCOTT, Clinton, MD (US); THOMAS K. JOHNSON, Ellicott City, MD (US); YUKLUN LEUNG, Silver Spring, MD (US); MICHAEL R. LIN, Ellicott City, MD (US)

(21) Appl. No.: 14/855,001

(22) Filed: Sep. 15, 2015

(51) Int. Cl. G01R 19/15; G01R 31/04

(52) U.S. Cl. CPC G01R 19/15; G01R 31/04

(57) ABSTRACT

A method of safe to mate testing includes providing a file of netlist signals where each signal defines a first connection to one or more components of a unit under test, connecting a first terminal of a measuring device to a first netlist signal and connecting a second terminal of the measuring device to a second netlist signal, performing a plurality of first resistive measurements by applying power having a first polarity between the first and second netlist signals, performing at least one second resistive measurement by applying power having a second polarity to the first and second netlist signals, and recording an average of the first resistive measurements and, if the second polarity measurement yields a negative result, an indication that a reactive load is connected between the first and second netlist signals.

### INVENTION BY GOVERNMENT EMPLOYEE(S) ONLY

The invention described herein was made by an employee of the United States Government, and may be manufactured and used by or for the Government for governmental purposes without the payment of any royalties thereon or therefor.

### BACKGROUND

The disclosed embodiments generally relate to electrical measurement processes and more particularly to verifying electrical characteristics of a device before connecting and applying power to the device.

Safe to mate testing is a common hardware safety practice where pin to pin measurements are made on unpowered hardware to verify characteristics such as isolation, continuity, or impedance between pins of an interface connector. Performing safe-to-mate testing on expensive critical equipment such as flight hardware and associated ground support equipment reduces the risk of failure upon power up and connection to other equipment. Historically, safe-to-mate measurements are performed manually with data written into paper forms. Multiple people may be involved, for example, a person to make measurements and another person to record the results. In addition, the tests may have to be repeated multiple times, for example, during different stages of development, before integration with other equipment, or when performing different qualification tests, such as environmental, electromagnetic radiation, etc. This laborious process potentially requires large amounts of time, in particular when testing connectors that might have as many as 104 pins or more. Furthermore, there is a high potential for errors, including contacting incorrect pins, reading the measuring device incorrectly, setting the measuring device incorrectly, variations among measurement devices, recording the measurements incorrectly, and loss of the hardcopy data. In addition, some measurement devices may have output levels that may damage sensitive circuitry.

It would be advantageous to provide a method and apparatus to perform safe to mate operations that overcome these and other disadvantages.

### SUMMARY

In at least one embodiment, a method of safe to mate testing includes providing a file of netlist signals where each signal defines a first connection to one or more components of a unit under test, connecting a first terminal of a measuring device to a first netlist signal and connecting a second terminal of the measuring device to a second netlist signal, performing a plurality of first resistive measurements by applying power having a first polarity between the first and second netlist signals, performing at least one second resistive measurement by applying power having a second polarity to the first and second netlist signals, and recording an average of the first resistive measurements and, if the second polarity measurement yields a negative result, an indication that a reactive load is connected between the first and second netlist signals.

The method may also include limiting an output of the measurement device while performing the resistive measurements.

The plurality of first resistive measurements may include three measurements.

Performing the plurality of first resistive measurements may include performing first resistive measurements repetitively until the resistance measurement is constant within a predetermined tolerance range or until a predetermined measurement count is reached.

The method may also include connecting the second terminal to a third netlist signal, performing the first and second resistive measurements, and recording an average of the first resistive measurements and, if the second resistive measurement yields a negative result, an indication that a reactive load is connected to between the first and third netlist signals.

The method may further include providing a file of harness signals, where one or more of the harness signals defines a second connection between components of a test system and at least one of the netlist signals, verifying that the first connections defined by each individual netlist signal have less than a continuity threshold resistance with respect to each other, verifying that the first connections defined by different netlist signals have more than a first isolation threshold resistance with respect to each other, and verifying that the harness signals not defining a second connection have more than a second isolation resistance with respect to each of the netlist signals;

The continuity threshold resistance may be approximately 20Ω.

The first isolation threshold resistance may be approximately 1MΩ.

The second isolation threshold resistance may be approximately the same as the first isolation threshold resistance.

According to some embodiments, a safe to mate test system includes a measurement device; a switch multiplexer connected to first and second terminals of the measuring device, control circuitry. The control circuitry is operable to load a file of netlist signals, where each signal defines a first connection to one or more components of a unit under test, cause the switch multiplexer to connect the first and second terminals of the measuring device to a first and second netlist signal, respectively, cause the measuring device to perform a plurality of first resistive measurements by applying power having a first polarity to the first and second netlist signals, and to perform at least one second resistive measurement by applying power having a second polarity to the first and second netlist signals, and record an average of the first resistive measurements and, if the second polarity measurement yields a negative result, an indication that a reactive load is connected between the first and second netlist signals.

The system may include a resistor connected in parallel with the first and second terminals to limit an output of the measurement device while performing the resistive measurements.

The plurality of first resistive measurements may include three measurements.

The control circuitry may be further operable to cause the measurement device to perform the first resistive measurements repetitively until the resistance measurement is constant within a predetermined tolerance range or until a predetermined measurement count is reached.

The control circuitry may be further operable to cause the switch multiplexer to connect the second terminal to a third netlist signal, cause the measuring device to perform the first and second resistive measurements, and record an average of the first resistive measurements and, if the second resistive measurement yields a negative result, an indication that a reactive load is connected between the first and third netlist signals.

The control circuitry may be operable to load a file of harness signals, where one or more of the harness signals defines a second connections between components of a test system and at least one the netlist signals, cause the switch multiplexer to connect the first and second terminals of the measuring device between the first connections defined by each individual netlist signal to measure a continuity threshold resistance between each first connection defined by each individual netlist signal, cause the switch multiplexer to connect the first and second terminals of the measuring device between each first connection defined by different netlist signals to measure a first isolation threshold resistance between each of the first connections defined by the different netlist signals, and cause the switch multiplexer to connect the first and second terminals of the measuring device between each harness signal not defining a second connection and each netlist signal to measure a second isolation threshold resistance between each harness signal not defining a second connection and each netlist signal.

The continuity threshold resistance may be approximately 20Ω.

The first isolation threshold resistance may be approximately 1MΩ.

The second isolation threshold resistance may be approximately the same as the first isolation threshold resistance.

### BRIEF DESCRIPTION OF THE DRAWINGS

The foregoing aspects and other features of the embodiments are explained in the following description, taken in connection with the accompanying drawings, wherein:

FIG. 1 shows an exemplary block diagram of the safe to mate system;

FIG. 2A shows a block diagram of a controller for use with the disclosed embodiments;

FIG. 2B shows a block diagram of a measurement device for use with the disclosed embodiments;

FIG. 2C shows a block diagram of switch multiplexers for use with the disclosed embodiments;

FIG. 2D shows a block diagram of an exemplary embodiment of the conductor arrangement connecting the multiplexers to the backplane and the backplane to the unit under test according to the disclosed embodiments;

FIGS. 3A and 3B show an exemplary embodiment of a backplane for use with the disclosed embodiments;

FIG. 3C shows an exemplary schematic of the connections provided by the backplane;

FIG. 4 shows a block diagram of software functions for operating the safe to mate system;

FIG. 5 shows an example of a calibration plug for use with the disclosed embodiments;

FIG. 6 shows an example of a harness file for use with the disclosed embodiments;

FIG. 7 shows an example of a netlist file for use with the disclosed embodiments;

FIG. 8 shows an example of a learn procedure file for use with the disclosed embodiments;

FIGS. 9A and 9B show an example of a learn report file for use with the disclosed embodiments.

FIG. 10 shows an example of an ohm file for use with the disclosed embodiments;

FIG. 11 shows an example of a test procedure file for use with the disclosed embodiments; and

FIG. 12 shows an example of a test report file for use with the disclosed embodiments.

### DETAILED DESCRIPTION

The disclosed embodiments are directed to an automated safe to mate (ASTM) apparatus and method that provides automated safe to mate testing for one or more connectors. Repetitive measurements are made automatically and results are recorded electronically. Components of the system are integrated together so that measurements may be made at different stages of development and over the lifespan of devices under test using the same equipment.

The ASTM system generally utilizes netlist files describing connections between components on a unit under test, and harness files describing the connections between the ASTM system and the unit under test, to automatically determine common node connections, isolation measurements, and resistive measurements among nodes on the unit under test. A learning function records open, shorted, and resistive measurements of a known good unit and saves them to a file for use during a testing function where the recorded measurements are compared with subsequent resistive measurements of other units.

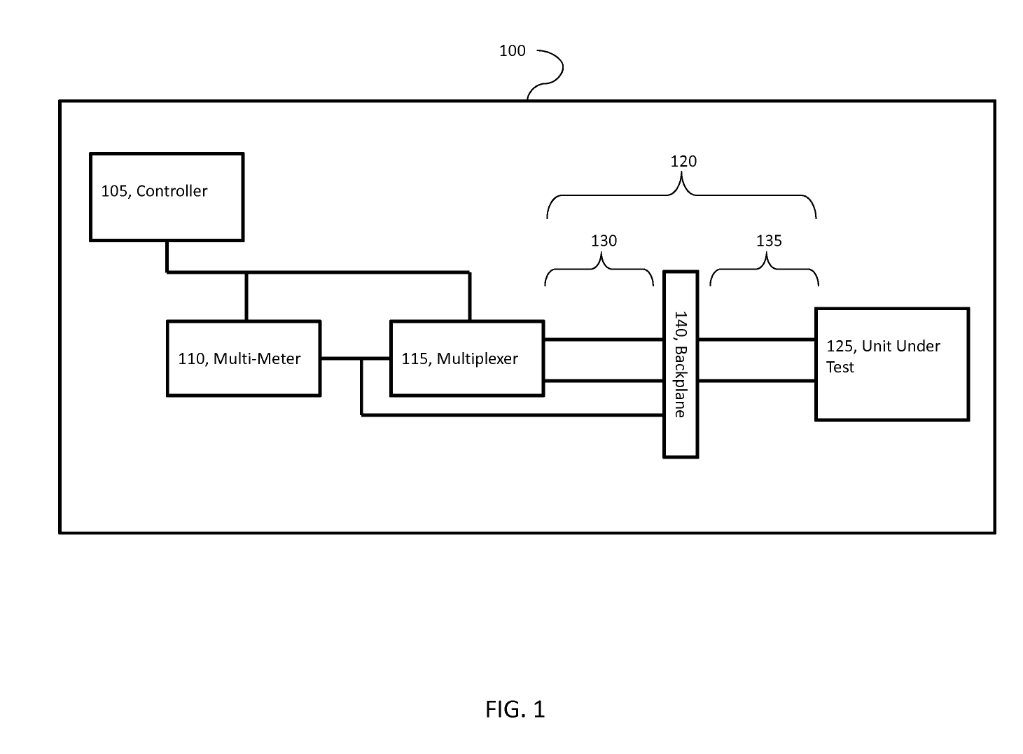

FIG. 1 shows a schematic block diagram of an exemplary safe to mate system 100 according to the disclosed embodiments. The system 100 includes a controller 105, a multi- meter 110, one or more switch multiplexers 115, and a conductor arrangement 120 for connecting the switch multiplexers 115 to a unit under test 125. The conductor arrangement 120 may include at least one or more harness arrangements 130, 135 and a backplane 140.

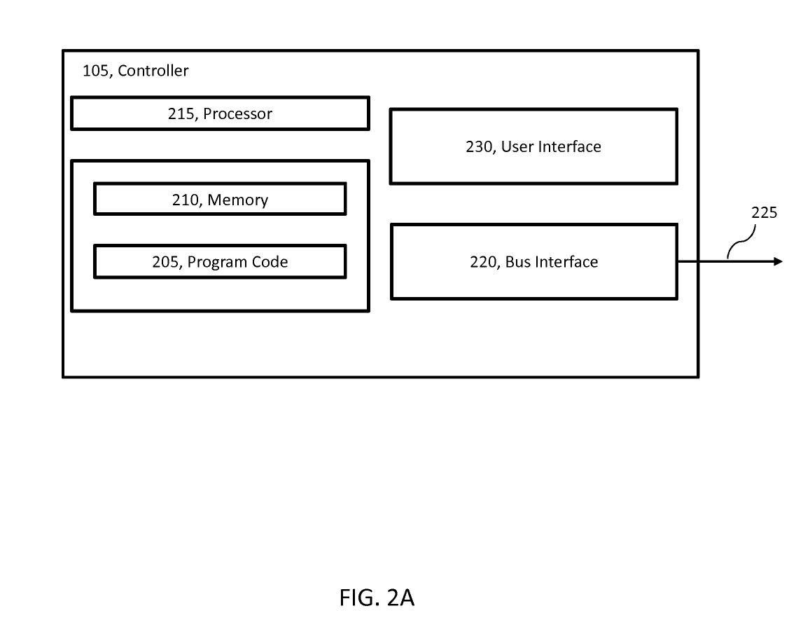

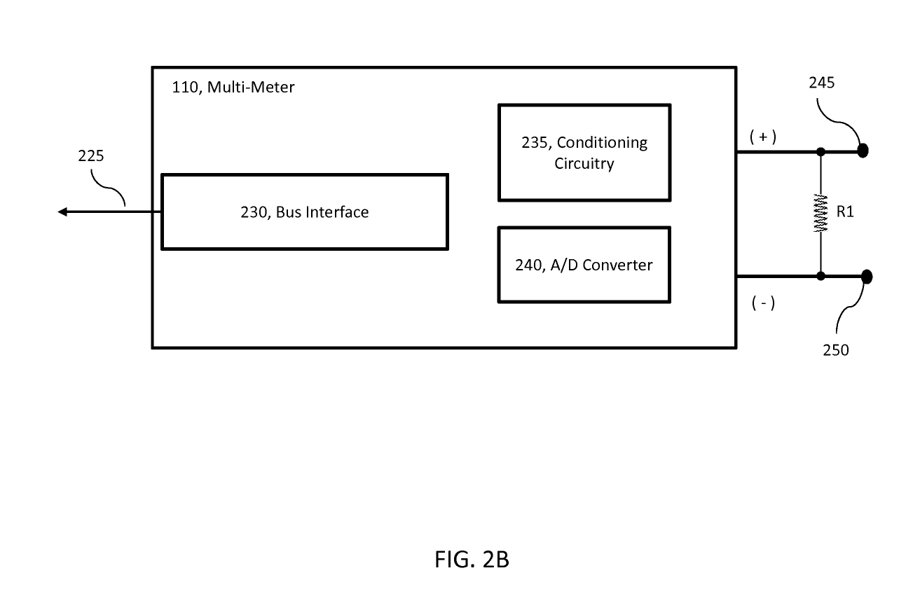

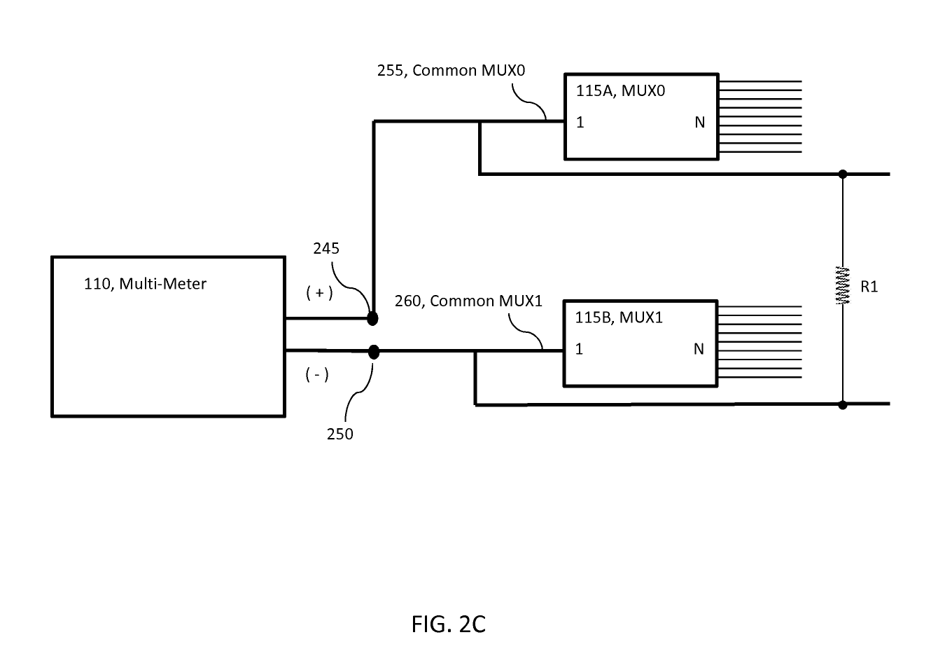

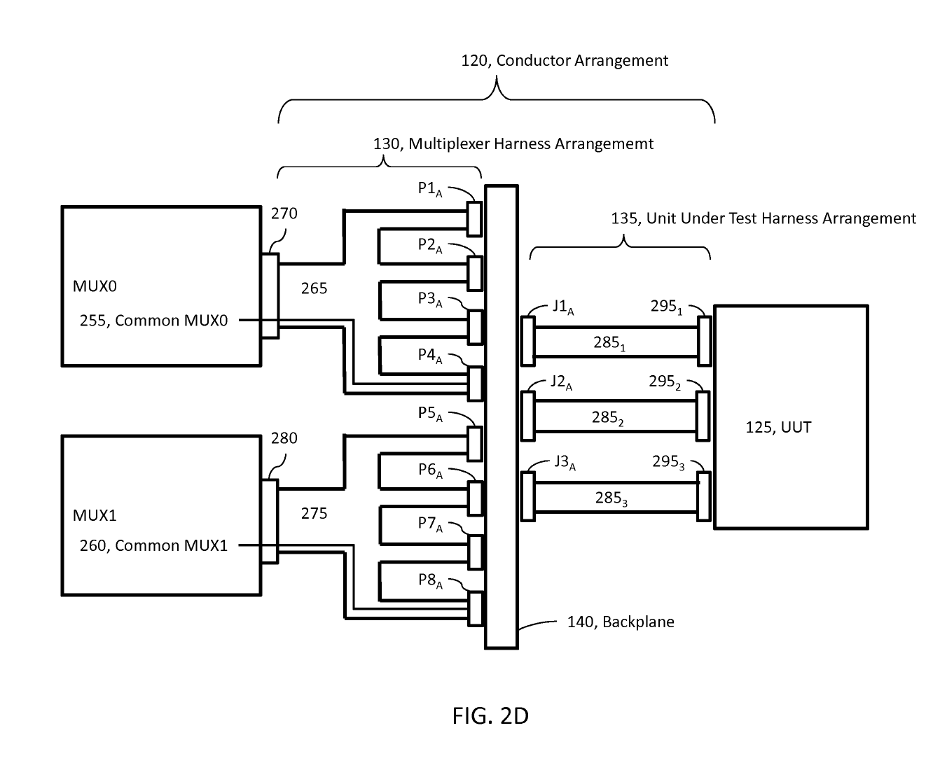

As shown in FIG. 2A, the controller 105 generally includes computer readable program code 205 stored on at least one computer readable medium for carrying out and executing the process steps described herein. The computer readable medium may be a memory 210 of the controller 105. In alternate aspects, the computer readable program code may be stored in a memory external to, or remote from, the controller 105. The memory 210 may include magnetic media, semiconductor media, optical media, or any media which is readable and executable by a computer. The controller 105 may also include a processor 215 for executing the computer readable program code 205. In at least one aspect, the controller 105 may include one or more input or output devices, including an interface 220 that provides a bus 225 for communicating with the multi-meter 110, the switch multiplexers 115, and other system components, and a user interface 230 for exchanging information and commands with a user.

As shown in FIG. 2B, the multi-meter 110 may have an interface 230 connected to the bus 225 for communicating with the controller 105 and the switch multiplexers 115. The multi-meter 110 may be programmed by the controller 105 to measure resistance, voltage, current, power, capacitance, inductance, frequency, or any other suitable electrical parameter. The multi-meter 110 generally uses conditioning circuitry 235 and an analog to digital converter 240 to effect the measurements. While the disclosed embodiments are discussed in terms of two wire measurements, it should be understood that four wire measurements may also be made by the system 100. In at least one embodiment, the voltage and current of the multi-meter 110 used for measurements may be limited to avoid damaging components under test. In one non-limiting example, the measurement voltage and current may be limited to 20 mV and 10 μA DC, respectively. Other limits to the measurement voltage and current may also be imposed depending on circuitry and components included in the unit under test 125. The multi-meter 110 may have at least a positive terminal 245 and a negative terminal 250 for performing measurements. In at least one embodiment, a resistor R1 may be connected in parallel with the terminals 245, 250 to limit the voltage output of the multi-meter 110 to avoid damaging the components under test. The resistance of R1 may be selected to limit the maximum voltage to a particular value.

Turning to FIG. 2C, at least one embodiment of the system includes switch multiplexers 115 in one or more groups of two MUX0, MUX1. The switch multiplexers may use electromechanical relays and may be configured to have N to 1 one wire channels with the common channel 255 of one of the group, for example, MUX0, connected to the positive terminal 245 of the multi-meter 110 and the common channel 260 of the other switch multiplexer of the group, for example MUX1, connected to the negative terminal 250 of the multi-meter 110. The common channels 255, 260 may also be connected to the backplane 140 through a multiplexer harness arrangement as explained in detail below. Some embodiments may be implemented with 196 to 1 one wire switch multiplexers. Resistor R1, connected to the terminals 245, 250 of the multi- meter 110, may be located remotely, for example, on backplane 140.

An exemplary embodiment of the conductor arrangement 120 is shown in FIG. 2D. A multiplexer harness arrangement 130 may be used to connect the multiplexers MUX0, MUX1, to a backplane 140. The multiplexer harness arrangement 130 generally includes a first harness 265 having a connector 270 connected to multiplexer MUX0 and one or more connectors P1_{A}-P4_{A} connected to the backplane 140. The first harness 265 provides connections between channels of the multiplexer MUX0 and the connectors P1_{A}-P4_{A} connected to the backplane 140. At least one of the conductors of first harness 265 may provide a connection between the common channel 255 of multiplexer MUX0 and the backplane 140. For example, the common channel 255 of multiplexer MUX0 may be connected to at least one pin of connector 270 and to at least one pin of connector P4_{A}. The multiplexer harness arrangement 130 may also include a second harness 275 having a connector 280 connected to multiplexer MUX1 and one or more connectors P5_{A}-P8_{A} connected to the backplane 140. The second harness 275 provides connections between channels of the multiplexer MUX1 and the connectors P5_{A}-P8_{A} connected to the backplane 140. At least one of the conductors of second harness 275 may provide a connection between the common channel 260 of multiplexer MUX1 and the backplane 140. For example, the common channel 260 of multiplexer MUX1 may be connected to at least one pin of connector 275 and to at least one pin of connector P8_{A}. As a non-limiting example, connectors 270, 280 may be 200 pin connectors that mate with corresponding connectors on multiplexers MUX0, MUX1, while connectors P1_{A}-P4_{A} and P5_{A}-P8_{A} may be a number of 50 pin connectors that mate with corresponding connectors on the backplane 140. While the multiplexer harness arrangement 130 is shown as two harnesses with two connectors connected to the multiplexers and four connectors connected to the backplane, it should be understood that any number of harnesses and connectors may be used to implement the multiplexer harness arrangement 130.

A unit under test harness arrangement 135 may be used to connect the backplane 140 to the unit under test 125. The unit under test harness arrangement 135 may include one or more third harnesses 285₁-285_{N} with connectors J1_{A}-J3_{A} at one end connected to the backplane 140 and connectors 295₁-295₃ at another end connected to the unit under test 125. It should be understood that any number of harnesses and connectors may be used to implement the unit under test harness arrangement 135. As a non-limiting example, connectors J1_{A}-J3_{A} may be 78 pin connectors that mate with corresponding connectors on the backplane 140, while connectors 295₁-295_{N} may also be 78 pin connectors. As another non-limiting example, connectors J1_{A}-J3_{A} may be 104 pin connectors while connectors 295₁-295_{N} may also be 104 pin connectors. As a further non-limiting example, connectors J1_{A}-J3_{A} may be any combination of 78 and 104 pin connectors while connectors 295₁-295_{N} may be any combination of connectors having any number of pins.

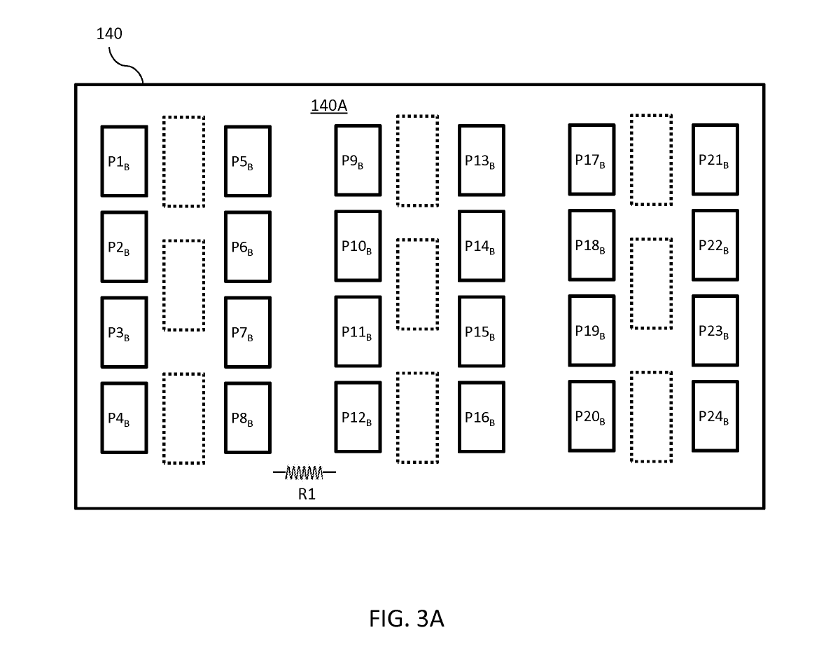

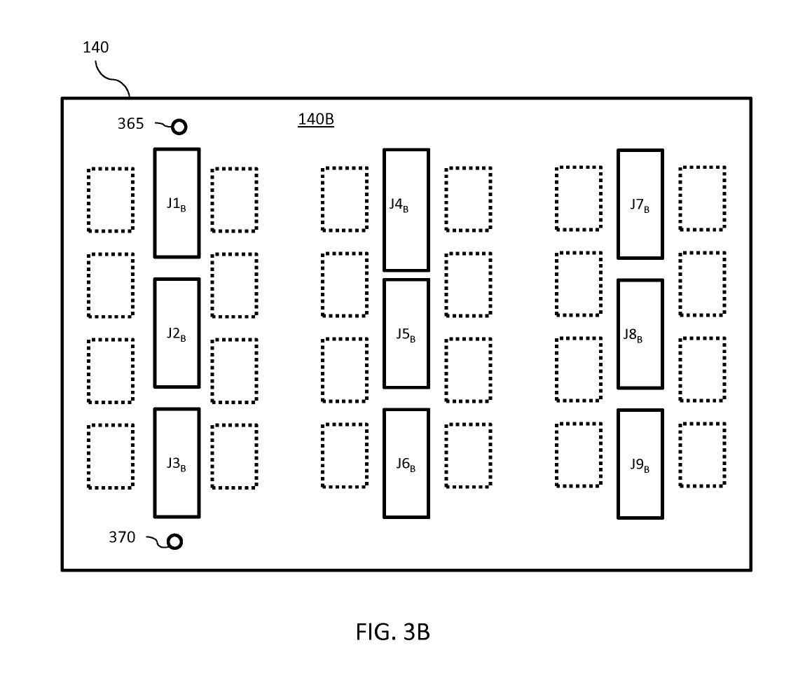

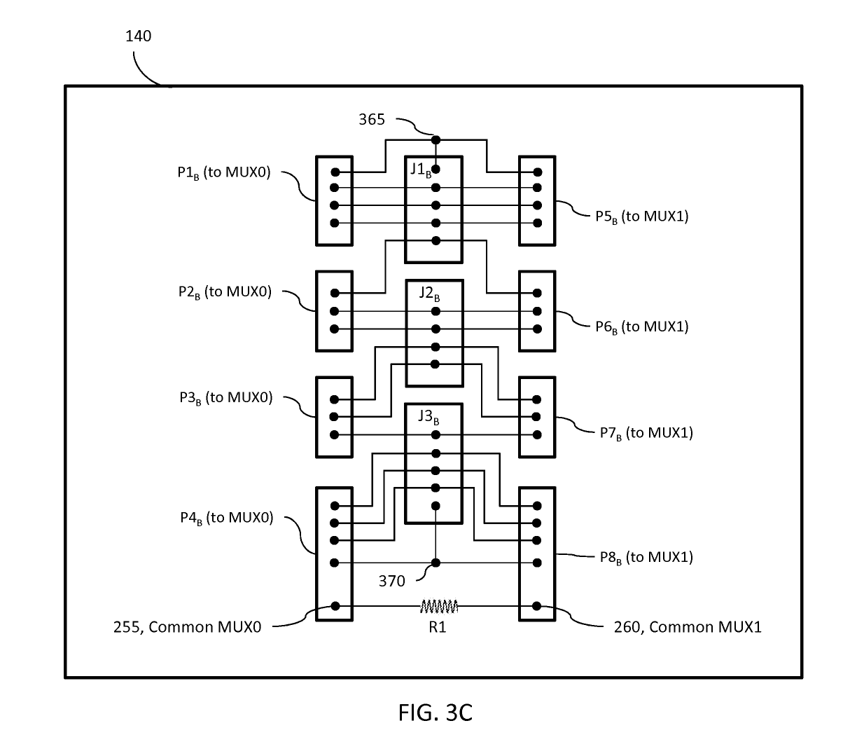

FIGS. 3A and 3B show exemplary embodiments of the backplane 140. FIG. 3A shows connectors P1_{b}-P4_{B}, P5_{B}-P8_{B}, P9_{b}-P12_{B}, P13_{B}-P16_{B}, Pl7_{b}-P20_{B}, and P21_{B}-P24_{B} for the multiplexer harness arrangement 130 on a first side 140A of the backplane 140. Resistor R1 described above may also be mounted on backplane 140, for example, on the first side 140A. FIG. 3B shows connectors J1_{b}-J3_{B}, J4_{B}-J6_{B}, and J7_{b}-J9_{B} for the unit under test harness arrangement 135 on a second side 140B of the backplane 140. For the example of the backplane 140 shown in FIG. 3A, connectors P1_{b}-P4_{B} and P5_{B}-P8_{B}, generally provide connection points for connectors P1_{A}-P4_{A} and P5_{A}-P8_{A}, respectively, of the multiplexer harness arrangement 130 (FIG. 2D). Turning to FIG. 3B, connectors J1_{B}-J3_{B} generally provide connection points for connectors J1_{A}-J3_{A} of the unit under test harness arrangement 135 (FIG. 2D). Additional connection points 365, 370 may be provided for connecting to points on the unit under test that are not accessible through the unit under test harness arrangement 135.

FIG. 3C shows an exemplary schematic of the connections provided by the backplane 140. Each pin of J1_{B}-J3_{B} is connected to at least one pin of P1_{B}-P4_{B} and also to at least one pin of P5_{B}-P8_{B}. In other words, one pin of each connector J1_{B}-J3_{B} for connection to the unit under test is connected to two pins, one pin of the multiplexer harness arrangement P1_{B}-P4_{B} for connection to MUX0 and one pin of the multiplexer harness arrangement P5_{B}-P8_{B} for connection to MUX1. The additional connection points 365, 370 may also be connected to one pin of the multiplexer harness arrangement P1_{B}-P4_{B} for connection to MUX0 and one pin of the multiplexer harness arrangement P5_{B}-P8_{B} for connection to MUX1. As described above, at least one pin of P1_{B}-P4_{B} may provide a connection between the common channel 255 of MUX0 and the resistor R1, and at least one pin of P5_{B}-P8_{B} may provide a connection between the common channel 260 of MUX1 and the resistor R1.

The backplane 140 stabilizes the connections from the multiplexers MUX0, MUX1, and provides a robust set of connection points to the unit under test that are less susceptible to damage. Connectors P1_{B}-P24_{B} may be selected so that standard, readily available harnesses may be used between the multiplexers MUX0, MUX1 and the backplane 140, and connectors J1_{B}-J9_{B} may be selected to allow for the use of custom harnesses specific to the unit under test between the backplane and the unit under test.

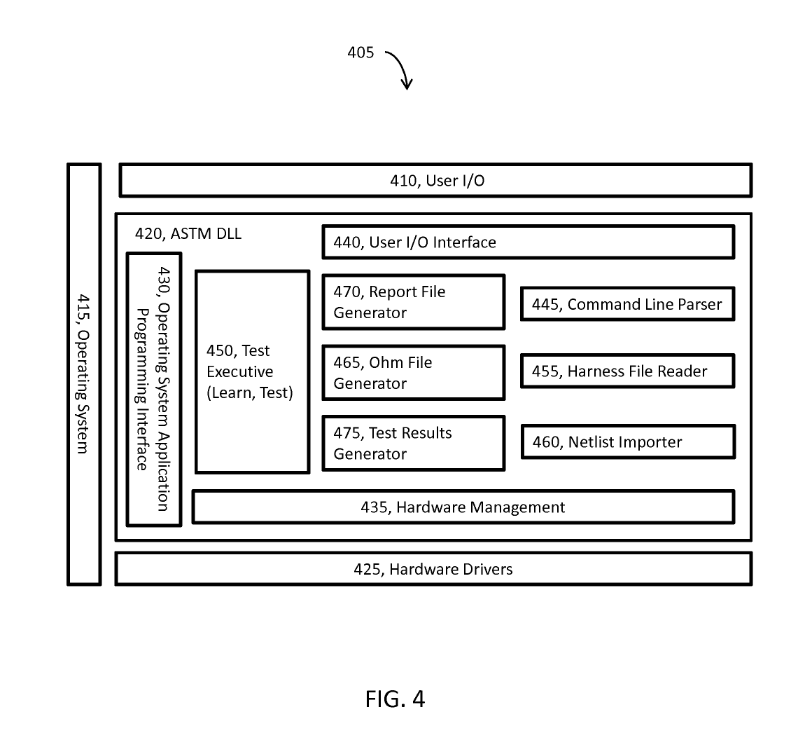

FIG. 4 shows a block diagram of the software functions 405 for operating the safe to mate system 100. The software functions 405 may be implemented in the computer readable program code 205 (FIG. 2A) stored in memory 210 of the controller 105. The functions 405 may include a user I/O function 410, an operating system 415, an Automated Safe To Mate (ASTM) DLL 420 and hardware drivers 425. The ASTM DLL 420 includes an operating system Application Programming Interface 430, a hardware management module 435, a User I/O interface 440, a command line parser 445, a test executive 450, a harness file reader 455, a netlist importer 460, an ohm file generator 465, a report file generator 470, and a test results generator 475.

The user I/O function 410 provides output and receives input using one or more user devices, for example, a display device, speaker microphone, touch screen, keyboard, mouse or other pointing device, or any device for receiving input from, or providing output to, a user. The user I/O function 410 may provide a window for displaying information about system operation, including test execution status, error indications, and an event log. The user I/O function 410 may also provide a facility for entering commands, for example using a command line interface, and for otherwise exchanging information with a user. The user I/O interface 440 operates to translate information from the software functions in the ASTM DLL 420 into a form for use by the User I/O 410. The user I/O interface 440 also operates to translate information from the user I/O into a form for use by the functions in the ASTM DLL 420 by using, for example, the command line parser 445.

The information about system operation may include conveying information about events as listed below. The number and types of events are exemplary and fewer or additional events may be utilized by the system.

| Event | Description |
|---|---|
| Initializing Switch Multiplexer | Indicates that a particular switch |
| | multiplexer is being initialized |
| Switch Multiplexer Initialized | Indicates that a particular switch |
| | multiplexer initialization is complete |
| Initializing Multimeter | Indicates that the multimeter is being |
| | initialized |
| Multimeter Initialized | Indicates that the multimeter initialization |
| | is complete |
| Shunt Resistor Calibrated | Provides value of the resistor in parallel |
| | with the multimeter |
| Y Resistance Calibrated | Provides resistance value of the harness |
| | arrangements |
| ASTM Initialization Complete | Indicates that the system initialization is |
| | complete |
| Measuring: Checking Continuity | An event that will initialize all the signals |
| | present on the process (.prc) file |
| Measuring: Checking Isolation | An event is displayed each time a |
| channelName (netListName): | measurement is made. The information in |
| channelName (netListName) = | the event provides a symbolic name for |
| valueInOhms | the positive and negative channels based |
| | on the wiring map, as well as the net list |
| | signal name associated with each pin |
| Measurement Complete, Generating | As the result of an ASTM Learn or ASTM |
| Reports | Test procedure, measurements are |
| | complete and .ohm, .rpt. and .tst files are |
| | being generated |
| Measurement Aborted, Generating Partial | An ASTM Abort command was received |
| Reports | during an ASTM Learn or ASTM Test |
| | procedure, measurements are not |
| | complete but partial and .ohm, .rpt. and |
| | .tst files are being generated with the |
| | completed measurements |
| Learn Complete - see <filename>.rpt and | As the result of an ASTM Learn |
| <filename>.ohm for details | procedure, measurements are complete |
| | and .ohm and .rpt files have been |
| | generated |
| Test Complete- see <filename>.tst and | As the result of an ASTM Test procedure, |
| <filename>.ohm for details | measurements are complete and .ohm and |
| | .tst files have been generated |
| Safe To Mate: Failed | As the result of an ASTM Test procedure, |
| | the characteristics of the unit under test |
| | did not match the characteristics of the |
| | “golden file” |
| Safe To Mate: OK | As the result of an ASTM Test procedure, |
| | the characteristics of the unit under test |
| | matched the characteristics of the “golden |
| | file” |
| Measurement Aborted | An ASTM Abort command was received |
| | during an ASTM Test procedure and no |
| | files are being generated. |
| Waiting for Initialization to Complete | A command has been received before the |
| | system has completed initialization |

A list of exemplary commands that may be accepted by the system through the user I/O 410 is shown below. Fewer or additional commands may be utilized by the system.

ABORT—An abort command may be used to abort or stop any measurement sequence that is currently in process. Report files such as .OHM and .RPT files may be generated but the results will be noted as incomplete.

ADDSIG—The addsign command may be used for adding non-connectorized test points and/or chassis ground signals to a measurement sequence. The specified signal will be associated with the specified connection point.

CAPFLOOR—The CAPFLOOR command is used to change the minimum allowable resistance between capacitively coupled signals from a default value of 50M.

CAPTOLERANCE—If a signal pair is found to be capacitively coupled, the corresponding resistance should be greater than the CAPFLOOR value in order to prevent a warning during the “LEARN” process. If the resistance of a capacitively coupled signal pair is not greater than the CAPFLOOR value, the resistance may still be acceptable, and the CAPTOLERANCE command may be used to change the resistive tolerance for capacitively coupled pins from a default value of 20%.

CHARGECOUNT—If a signal pair is found to be capacitively coupled, the safe to mate system will attempt to charge the capacitor to verify that the signal pair is not shorted together. The multi-meter supplies power during measurements and the signal may be iteratively measured in order to charge the capacitor. The system may be programmed to stop the iterative measurements after a certain number of measurements or when a resistance across the capacitor stops increasing. The CHARGECOUNT command may be used to change the number of measurements from a default value of 1000.

CHARGEDELAY—As mentioned above, if a signal pair is found to be capacitively coupled, the safe to mate system will attempt to charge the capacitor to verify that the signal pair is not shorted together. The multi-meter supplies power during measurements and the signal may be iteratively measured in order to charge the capacitor. . A delay may be introduced between measurement iterations to allow the capacitor to respond to the newly added charge. The CHARGEDELAY command may be used to change the time between each iteration from a default value of 100 milliseconds.

CURRENTVALS—The CURRENTVALS command will display the current values for the CAPTOLERANCE, CAPFLOOR, CHARGECOUNT, CHARGEDELAY, MINRES, MAXRES, and TOLERANCE commands.

CD—Users are expected to place all data files for specific projects in a single project level subdirectory within the file structure of the safe to mate system. The CD command is used to navigate among subdirectories within the system file structure.

DEFINESHORT—The DEFINESHORT command is used to logically connect together discrete netlist signals that are actually connected together but might not be shown on the netlist, for example, AGND and DGND, or GND and CGND.

HARNESS—In order to connect the ASTM system to a unit under test, a harness may be constructed that connects the back-plane connectors and the DUT connectors. The HARNESS command is used to specify the name of the harness file that the safe to mate system will use to test the unit under test.

HELP—The HELP command will list all the safe to mate commands.

LEARN—The LEARN command will execute a learn operation using specified harness and netlist files.

MEASURE—The MEASURE command will make a measurement between two specific signals. The switch multiplexers are left connected to the specific signals so that a manual measurement of the same signal pair may be performed. It should be noted that the manual measurement will typically include a measurement of the 2KΩ parallel resistor, while the measurement reported by the safe to mate system will have factored out the 2KΩ parallel resistor.

MINRES—The MINRES command is used to change the minimum resistance that the system will be used as a reference to declare a short. The minimum resistance by default is 20Ω.

MAXRES—The MACRES command is used to change the maximum resistance that the system will used as a reference to declare isolation. The maximum resistance by default is 1MΩ.

NETLIST—The Netlist command is used to import a netlist for a unit under test and to map the connector pins on the unit under test to the connector pins of the multiplexer harness arrangement.

SERNUM—The SERNUM command is used to give a serial number that will be appended to the .rpt and .ohm file names.

SKIPNCS—The SKIPNCS command is used to skip the signal pins that are not connected. This may advantageously decrease test time.

TEST—The TEST command is used to execute a test operation using specified harness, netlist, and golden reference for comparison with a DUT.

TOLERANCE—The TOLERANCE command is used to change the overall tolerance for measurements when comparing the measurements of the unit under test to those of the golden file.

Returning to FIG. 4, the operating system 415 may comprise any suitable operating system, for example, Windows, LINUX, OS X, or any other operating system suitable for managing the hardware and software components of the safe to mate system 100. The hardware management module 435 generally controls initialization and configuration of the hardware drivers 425, the multi-meter 110, and the multiplexers MUX0, MUX1 and exchanges information between the hardware drivers 425 and the system functions. The hardware drivers 425 operate to translate general system commands from the hardware management module to hardware specific commands for the multi-meter 110, and the multiplexers 115A, 115B. The operating system Application Programming Interface 430 provides a software interface for calls between the system functions and functions of the operating system 415.

The test executive 450 controls operations for the safe to mate system. The ASTM system performs two major types of operations: learn and test. The learn operation is used to gather information about a unit under test for use in subsequent testing operations. The test operation compares the information gathered during the learn operation with information about another unit under test within pre-set tolerances and reports the results. The test operation can be performed to compare the information of the same unit after a rework is done and requires a safe-to-mate.

Upon start up, the test executive 450 uses the user I/O 410 to open a window and display an event log and a command prompt. The switch multiplexers MUX0, MUX1 and multi-meter 110 are initialized through the hardware management module 435 and hardware drivers 425. As each device is initialized a corresponding event message is displayed in the window. The test executive 450 also performs a calibration of the 2k Ω resistor, the multiplexer harness arrangement 130 and the backplane 140.

If calibration is required, a calibration plug 510 may be plugged into one of the unit under test harness arrangement connectors, for example J1_{A}-J3_{A}, on the backplane 140. FIG. 5 shows an example of a calibration plug 510 where at least one of connectors J1_{A}-J3_{A} is a 78 pin connector. It should be understood that connectors J1_{A}-J3_{A} may comprise any number of pins. The calibration plug 510 includes a number of electronic components with known values, for example, resistors, capacitors, diodes, inductors or any electronic component suitable for calibrating the safe to mate system 100. The test executive 450 then performs a calibration procedure and measures at least the values of the components. In some embodiments, the test executive 450 may measure the impedance between each individual pin and the other pins in the calibration plug. The test executive 450 then utilizes the report file generator 470 to generate a present calibration plug report file of all the measurements. The present calibration plug report file may be compared to a good calibration plug report file with known good values to determine if the values correspond within a pre-determined tolerance range. The test executive 450 may display the results of the calibration and may also proceed with further operations or wait for an intervention depending on the results. In other embodiments, the present calibration plug report file may be compared with the good calibration plug report file manually and the decision to proceed or not may be made by an operator.

The learn operation may be used to obtain characteristics of the unit under test harness arrangement 135 and known good unit under test for use in testing at least one other unit under test having the same characteristics.

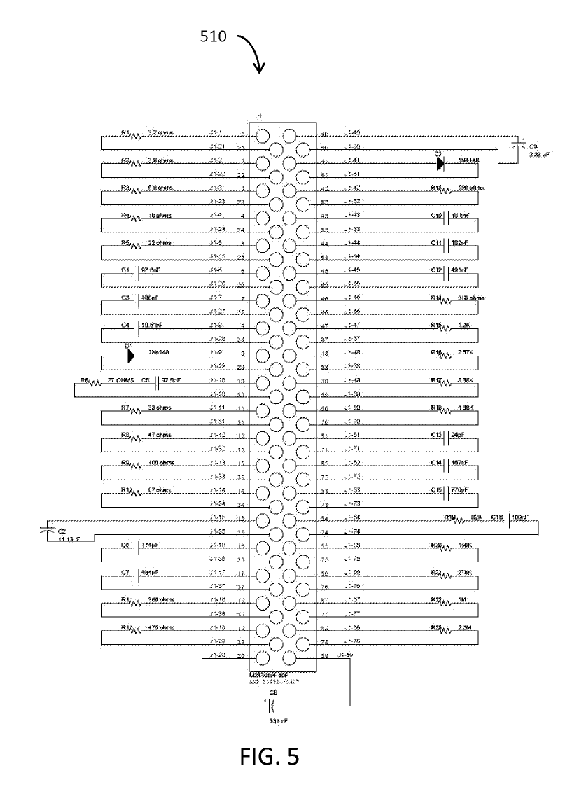

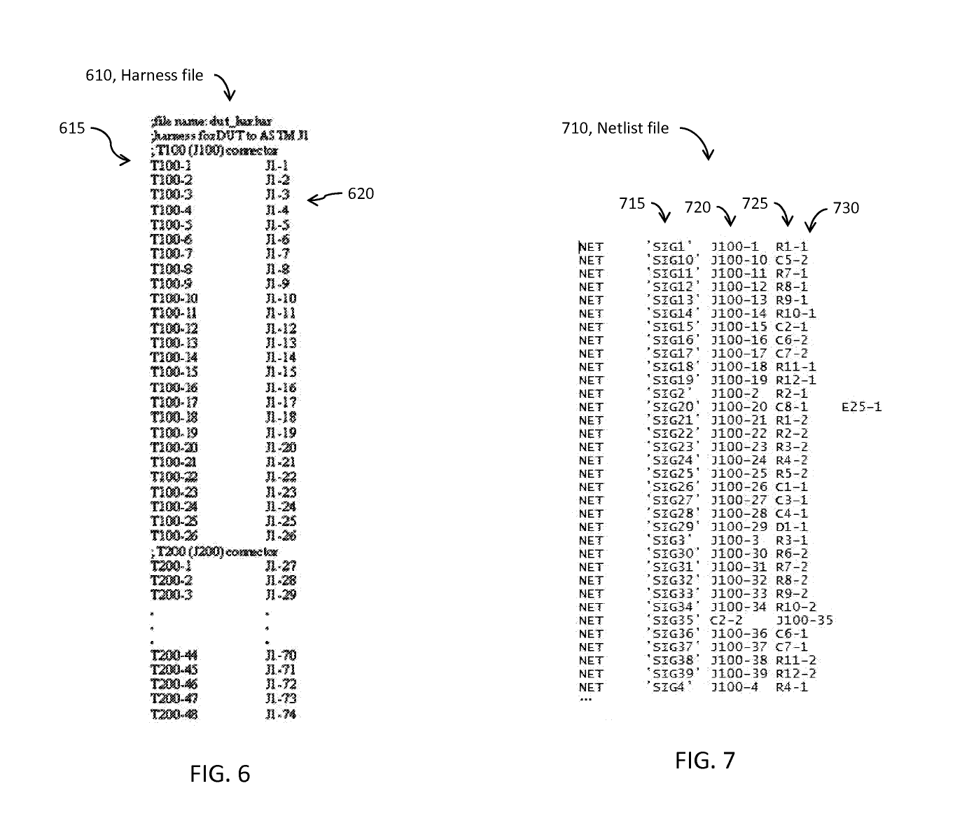

A harness file describing the connections provided by the unit under test harness arrangement 135 is compiled, for example by an operator, and may be stored in a known directory of the operating system 415. In at least one embodiment, the harness file includes one or more harness file signals that define connections between the connectors on the backplane 140, for example, J1_{B}-J9_{B}, and the connections defined by the netlist file described below. An exemplary harness file 610 is shown in FIG. 6. The harness file 610 generally provides information on how pins of the device under test 125 and the safe to mate system 100 will be mapped together and allows the test executive 450 to recognize which channels of the switch multiplexers to use for performing the learning and testing operations. In some embodiments, the harness file 610 may be an ASCII formatted file where each line includes a channel 615 of switch multiplexer and a pin 620 of connector 295₁-295_{N}. The harness file reader 455 obtains the harness file 610 and provides data from the harness file to the test executive 450.

A netlist file of signals, where each signal defines a connection to one or more components on the unit under test 125, is also stored in a known directory of the operating system 415. An exemplary netlist file 710 is shown in FIG. 7. The netlist file may be generated by a computer aided design system and may optionally include a description of each connected component on the unit under test 125. The netlist file may be an ASCII formatted file where each line includes a signal name 715, a pin 720 on the unit under test, and a reference designation identifying a component 725 and a terminal 730 of the component. The signal name 715 may designate a node to which the pin 720 and component terminal 730 are connected. The netlist importer 460 retrieves the netlist 710 and makes it available to the test executive 450.

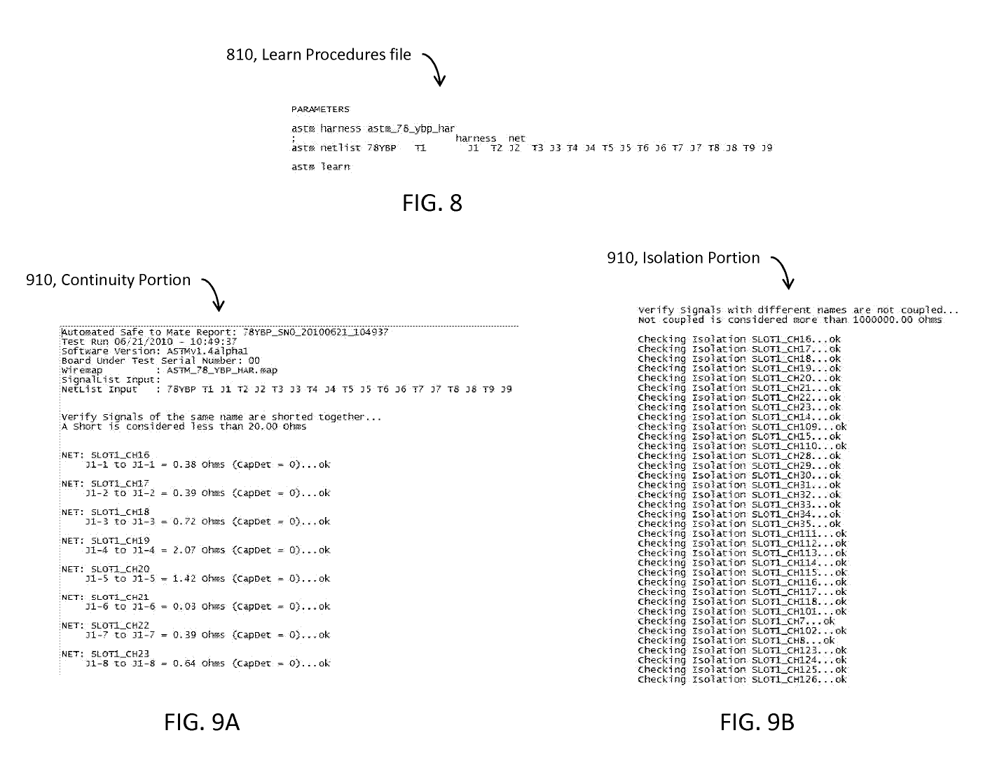

A learn procedure file is prepared that specified parameters for operating a learn operation. An exemplary learn procedure file 810 is shown in FIG. 8. The first line provides the keyword PARAMETERS, the second line loads the harness file, and the third line loads the netlist file. The third line also specifies a mapping of the connectors from the harness file to the connectors of the unit under test.

The test executive 450 initiates the learn operation by loading the harness file 610, netlist file 710, and learn procedures file 810, and then starting a scan which measures the resistance of each pin listed in the harness file with respect to every other pin.

In at least one embodiment, the test executive may first operate the multiplexers MUX0, MUX1 and the multi-meter 110 to verify that all pins with the same signal name 715 in the netlist 710 are connected with less than a continuity threshold resistance. For example, an exemplary continuity threshold resistance may be defined as a resistance of less than approximately 2052 where there are no reactive components connected to the node.

The test executive may then operate the system components to perform isolation measurements that verify that all pins with different signal names 715 in the netlist 710 are not connected, that is, have a resistance with respect other pins with different signals names that exceeds a threshold. For example, an isolation threshold resistance may be defined as a resistance greater than approximately 1MΩ.

The test executive may then operate the system to perform a “no-connect” test where any signals in the harness file but not in the netlist 710 are tested to ensure that they are isolated. In other words, any signals in the harness file but not in the netlist 710 are assumed to be isolated from each other and all other signals. A test threshold for no-connect signals may be the same as for pins with different signals names, for example, an isolation resistance that exceeds approximately 1MΩ, or any other suitable test threshold.

The test executive 450 may then proceed to perform a resistance test on pins connected to terminals of a resistive device, for example, a resistor, as indicated by the netlist 710. A set of pins to be tested is selected and the multiplexers MUX0, MUX1 are used to connect the multi-meter to the pins with a first polarity. A plurality of resistance measurements are taken and in some embodiments an average of the resistance measurements is recorded.

Different measurements may be performed on pins connected to terminals of a reactive device, for example, a capacitor or inductor, as indicated by the netlist 710. For pins designated as being connected to terminals of a reactive device, the test executive 450 may perform multiple first polarity measurements in order to charge the device. In at least one embodiment, the test executive 450 performs first polarity measurements repetitively until the resistance measurement becomes constant within a predetermined tolerance range or until a predetermined test count is reached. The predetermined tolerance range may be set by the CAPTOLERANCE command, the predetermined test count may be set by the CHARGECOUNT command, and a delay between measurements may be set by the CHARGEDELAY command. Once the first polarity measurements have been completed, to further verify the presence of the reactive device, the test executive may take at least one opposite polarity measurement, typically resulting in a negative reading. A CAP field in the ohms file 810 may be utilized to designate a capacitive measurement result. At least one other field may be used to designate an inductive measurement result.

The test executive 450 compares the connections of the unit under test with the netlist file and uses the report file generator 470 to generate a learn report file of any deviations between the unit under test and the netlist file. An exemplary learn report file 910 is shown in FIGS. 9A and 9B. FIG. 9A shows a portion of the learn report file displaying continuity measurements, while FIG. 9B shows a portion of the learn report displaying isolation measurements, as explained below.

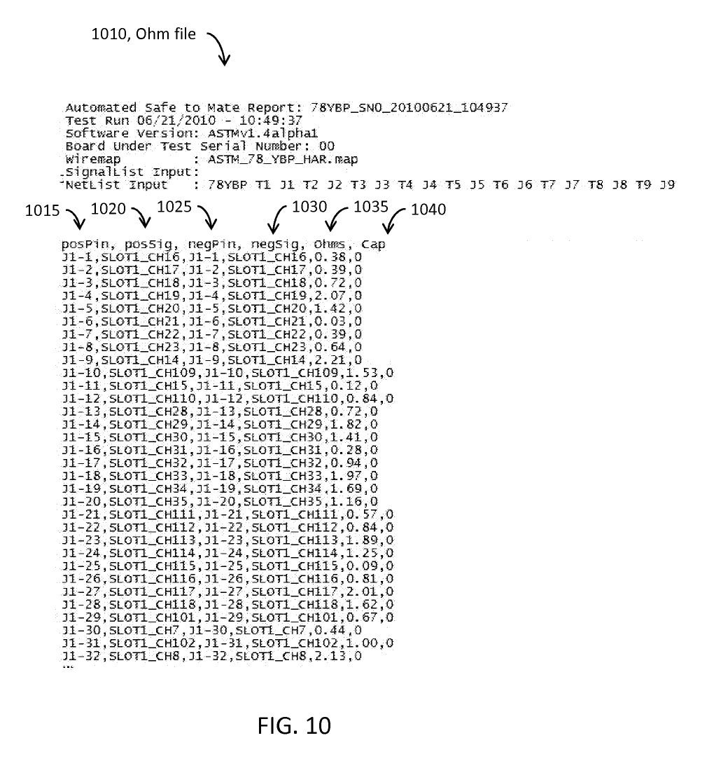

The test executive 450 uses the ohm file generator 465 to generate an ohm file including a list of each pin to pin resistance measurement. An exemplary ohm file 1010 is shown in FIG. 10. The ohm file 1010 may be an ASCII formatted file where each line includes a resistive measurement 1035, and an indication 1040 that the measurement is of a reactive load, for example, a capacitor. Each line may also include a pin 1015 on the unit under test harness and a channel 1020 of a switch multiplexer connecting the pin 1015 to the positive terminal 245 of the multi-meter 110. Each line may further include a pin 1025 on the unit under test harness and a channel 1030 of a switch multiplexer connecting the pin 1025 to the negative terminal 250 of the multi-meter 110.

Once the system has completed the learn procedure, an operator may check the learn report file 910 for deviations and check the ohm file 1010 to ensure that the recorded measurements are within specification. After the learn report and ohm files have been verified, the ohm file may be renamed as a .gld file, i.e., a “gold” file or reference file for testing additional units under test.

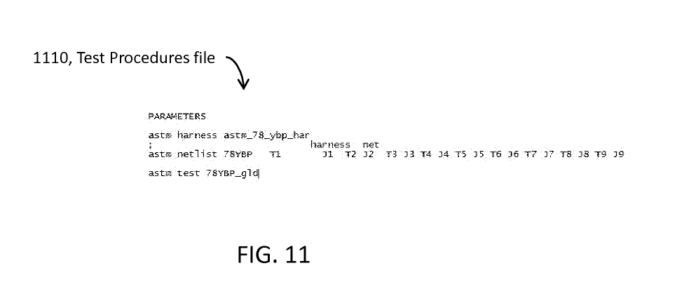

The test procedure includes preparing a test procedure file, an example of which is shown in FIG. 11. The test procedure file may be similar to the learn procedure file above. The first line provides the keyword PARAMETERS, the second line loads the harness file, and the third line loads the netlist file. The third line also specifies a mapping of the connectors from the harness file to the connectors of the unit under test.

The test executive 450 initiates the test operation on an unknown unit under test by loading the harness file 610, netlist file 710, golden reference file and test procedure file 1110, and then starting a scan which measures the resistance of each pin listed in the harness file with respect to every other pin.

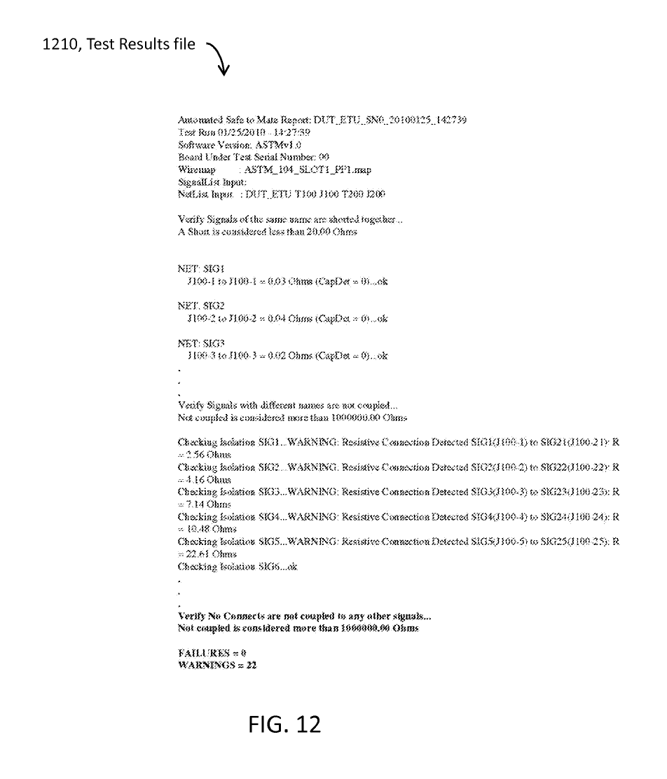

The test executive 450 performs substantially the same tests as the learn operation. While performing the ASTM test operation, the test executive 450 compares each measurement with the corresponding results in the golden reference file. If the measurements match within the specified tolerance range, the test executive will report a status of “OK” or other indication of a positive match, otherwise the test executive will report a status of “FAIL” or other indication that the measurement did not match the measurement recorded in the golden file. Upon completion, the test executive 450 uses the test results generator 475 to generate a test report file displaying the results, including the OK and FAIL indications. An exemplary test report file 1210 is shown in FIG. 12. The test results file 1210 may be similar to the learn results file 910 (FIG. 9). The test executive 450 also uses the Ohm file generator 465 to generate an ohm file 1010 (FIG. 10) for the present unit under test that shows a detailed list of the measurements performed during the test. An operator may review the test results file 1210 and the ohm file 1010 to determine if the measurements of the unit under test match those of the associated golden reference file within the specified tolerance range.

The disclosed ASTM system provides a comprehensive automated test that is uniform and repetitive for successive units under test, for example, for a batch of units under test that are identically built. The learn and test operations provide a unique measurement sequence that utilizes DC measurements to detect and characterize both resistive and reactive components, and are automated to improve throughput and consistency. The voltage and current of the multi- meter measurement device are limited to protect components of the unit under test. In addition, comprehensive digital records are provided for each individual unit under test that may be easily reviewed for anomalies, stored, preserved and provided to operators or other personnel for analysis or other purposes.

It is noted that the embodiments described herein can be used individually or in any combination thereof. It should be understood that the foregoing description is only illustrative of the embodiments. Various alternatives and modifications can be devised by those skilled in the art without departing from the embodiments. Accordingly, the present embodiments are intended to embrace all such alternatives, modifications and variances that fall within the scope of the appended claims.

1. A method of safe to mate testing comprising:
providing a file of netlist signals where each signal defines a first connection to one or more components of a unit under test;
connecting a first terminal of a measuring device to a first netlist signal and connecting a second terminal of the measuring device to a second netlist signal;
performing a plurality of first resistive measurements by applying power having a first polarity between the first and second netlist signals;
performing at least one second resistive measurement by applying power having a second polarity to the first and second netlist signals; and
recording an average of the first resistive measurements and, if the second polarity measurement yields a negative result, an indication that a reactive load is connected between the first and second netlist signals.

2. The method of claim 1, comprising limiting an output of the measurement device while performing the resistive measurements.

3. The method of claim 1, wherein the plurality of first resistive measurements comprise three measurements.

4. The method of claim 1, wherein performing the plurality of first resistive measurements comprises performing first resistive measurements repetitively until the resistance measurement is constant within a predetermined tolerance range or until a predetermined measurement count is reached.

5. The method of claim 1, further comprising:
connecting the second terminal to a third netlist signal;
performing the first and second resistive measurements; and
recording an average of the first resistive measurements and, if the second resistive measurement yields a negative result, an indication that a reactive load is connected to between the first and third netlist signals.

6. The method of claim 1, further comprising:
providing a file of harness signals, where one or more of the harness signals defines a second connection between components of a test system and at least one of the netlist signals;
verifying that the first connections defined by each individual netlist signal have less than a continuity threshold resistance with respect to each other;
verifying that the first connections defined by different netlist signals have more than a first isolation threshold resistance with respect to each other; and
verifying that the harness signals not defining a second connection have more than a second isolation resistance with respect to each of the netlist signals;

7. The method of claim 6, wherein the continuity threshold resistance is approximately 20Ω.

8. The method of claim 6, wherein the first isolation threshold resistance is approximately 1MΩ.

9. The method of claim 6, wherein the second isolation threshold resistance is approximately the same as the first isolation threshold resistance.

10. A safe to mate test system comprising:
a measurement device;
a switch multiplexer connected to first and second terminals of the measuring device; and
control circuitry operable to:
load a file of netlist signals, where each signal defines a first connection to one or more components of a unit under test;
cause the switch multiplexer to connect the first and second terminals of the measuring device to a first and second netlist signal, respectively;
cause the measuring device to perform a plurality of first resistive measurements by applying power having a first polarity to the first and second netlist signals, and to perform at least one second resistive measurement by applying power having a second polarity to the first and second netlist signals; and
record an average of the first resistive measurements and, if the second polarity measurement yields a negative result, an indication that a reactive load is connected between the first and second netlist signals.

11. The system of claim 10, comprising a resistor connected in parallel with the first and second terminals to limit an output of the measurement device while performing the resistive measurements.

12. The system of claim 10, wherein the plurality of first resistive measurements comprise three measurements.

13. The system claim 10, wherein the control circuitry is further operable to cause the measurement device to perform the first resistive measurements repetitively until the resistance measurement is constant within a predetermined tolerance range or until a predetermined measurement count is reached.

14. The system of claim 10, wherein the control circuitry is further operable to:
cause the switch multiplexer to connect the second terminal to a third netlist signal;
cause the measuring device to perform the first and second resistive measurements; and
record an average of the first resistive measurements and, if the second resistive measurement yields a negative result, an indication that a reactive load is connected between the first and third netlist signals.

15. The system of claim 10, wherein the control circuitry is operable to:
load a file of harness signals, where one or more of the harness signals defines a second connections between components of a test system and at least one the netlist signals;
cause the switch multiplexer to connect the first and second terminals of the measuring device between the first connections defined by each individual netlist signal to measure a continuity threshold resistance between each first connection defined by each individual netlist signal;
cause the switch multiplexer to connect the first and second terminals of the measuring device between each first connection defined by different netlist signals to measure a first isolation threshold resistance between each of the first connections defined by the different netlist signals; and
cause the switch multiplexer to connect the first and second terminals of the measuring device between each harness signal not defining a second connection and each netlist signal to measure a second isolation threshold resistance between each harness signal not defining a second connection and each netlist signal.

16. The system of claim 15, wherein the continuity threshold resistance is approximately 20Ω.

17. The system of claim 15, wherein the first isolation threshold resistance is approximately 1MΩ.

18. The system of claim 15, wherein the second isolation threshold resistance is approximately the same as the first isolation threshold resistance.
